(19) United States
(12) Patent Application Publication
(10) Pub. No.: US 2007/0069307 A1
(43) Pub. Date: Mar. 29, 2007

(54) Semiconductor device and method of manufacturing the same

(76) Inventor: Kentaro Eda, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/526,778

(22) Filed: Sep. 26, 2006

(30) Foreign Application Priority Data
Sep. 27, 2005 (JP) 2005-279375

(51) Int. Cl. H01L 29/76

(52) U.S. Cl. 257/374

(57) ABSTRACT

A semiconductor device includes a trench formed in a surface of a semiconductor substrate and defining a device region. A MOSFET includes a gate insulating film formed on the semiconductor substrate, a gate electrode formed on the gate insulating film, and a source/drain diffusion area sandwiching a channel region below the gate electrode. A stress film is continuously formed over the gate electrode and source/drain diffusion area and in the trench and applies a tensile stress or compressive stress to the semiconductor substrate. An insulating film buries the trench via the stress film.

### CROSS-REFERENCE TO RELATED APPLICATIONS

This application is based upon and claims the benefit of priority from prior Japanese Patent Application No. 2005-279375, filed Sep. 27, 2005, the entire contents of which are incorporated herein by reference.

### BACKGROUND OF THE INVENTION

1. Field of the Invention

The present invention relates to a semiconductor device and its manufacturing method and, for example, to a device isolation insulating film of a semiconductor device.

2. Description of the Related Art

As a device isolation insulating film for defining the device region (active area) of a semiconductor device, there is known a device isolation insulating film having a shallow trench isolation (STI) structure. The device isolation insulating film having an STI structure is formed by filling a trench formed in the surface of a semiconductor substrate with an insulating film. A semiconductor device such as a metal oxide semiconductor field effect transistor (MOSFET) is formed in the active area.

A technique is known that utilizes a stress that an insulating film constituting a device isolation insulating film applies to a semiconductor substrate to increase on-current of a MOSFET (hereinafter, referred to merely as transistor). The insulating film adapted to obtain on-current enhancement of the transistor using the stress is formed on the side surfaces in the trench. The remaining part of the trench is buried with an insulating film having, e.g., good burying properties.

A manufacturing method of a semiconductor device having the device isolation insulating film capable of obtaining on-current enhancement will be described with reference to FIGS. 14 to 16. As shown in FIG. 14, a silicon nitride film 102 is formed on a semiconductor substrate 101, and a trench 103 is formed through the silicon nitride film 102 into semiconductor substrate 101.

Subsequently, after a silicon nitride film 104 is formed on the inner surface of the trench 103, the trench 103 is buried with an insulating film 105 up to an appropriate level. A part of the silicon nitride film 104 that is exposed in the trench 103 is then removed. An insulating film 106 is formed in the trench 103. Finally, the silicon nitride film 102 is removed, forming a device isolation insulating film.

As shown in FIG. 15, a transistor having a gate insulating film 111, a gate electrode 112, and a source/drain diffusion area 113 is formed. As shown in FIG. 16, an etching stopper film 114 is formed on the entire surface of the structure obtained after the previous process. After that, an interlayer insulating film, a wiring layer, a contact plug, and the like are formed. The etching stopper film 114 functions as a stopper when a contact hole is formed through the interlayer insulating film.

A stress that the silicon nitride film 104 has acts on the channel region of the transistor to increase on-current of the transistor. The smaller a distance between the silicon nitride film 104 and channel region is, the larger the on-current enhancement can be.

Jpn. Pat. Appln. Publication No. 2003-158241 discloses that a silicon nitride film is formed on the side surfaces of the trench contacting the active area of an NMOS while a silicon nitride film is formed on the side surface of the trench contacting the active area of a PMOS only in channel direction and vertical direction to thereby increase on-current of both the NMOS and PMOS.

### BRIEF SUMMARY OF THE INVENTION

According to an aspect of the present invention, there is provided a semiconductor device comprising: a semiconductor substrate; a trench formed in a surface of the semiconductor substrate and defining a device region; a MOSFET including a gate insulating film formed on the semiconductor substrate, a gate electrode formed on the gate insulating film, and a source/drain diffusion area sandwiching a channel region below the gate electrode; a stress film continuously formed on the gate electrode and source/drain diffusion area and in the trench and applying a tensile stress or compressive stress to the semiconductor substrate; and an insulating film burying the trench via the stress film.

According to an aspect of the present invention, there is provided a method of manufacturing a semiconductor device comprising: forming a trench which defines a device region in a surface of a semiconductor substrate; forming a MOSFET on the surface of the semiconductor substrate, the MOSFET including a gate insulating film, a gate electrode formed on the gate insulating film, and a source/drain diffusion area sandwiching a channel region below the gate electrode; forming a continuous stress film on the gate electrode and source/drain diffusion area and in the trench, the stress film applying a tensile stress or compressive stress to the semiconductor substrate; and burying the trench with a first insulating film via the stress film.

### BRIEF DESCRIPTION OF THE SEVERAL VIEWS OF THE DRAWING

FIG. 1 is a plan view showing major parts of a semiconductor device according to an embodiment of the present invention;

FIGS. 2 and 3 are cross-sectional views of FIG. 1;

FIG. 4 is a cross-sectional view showing major parts of the semiconductor device according to another embodiment of the present invention;

FIG. 5 is a cross-sectional view showing a part of manufacturing steps of the semiconductor device shown in FIG. 2;

FIG. 6 is a cross-sectional view showing the manufacturing step after FIG. 5;

FIG. 7 is a cross-sectional view showing the manufacturing step after FIG. 6;

FIG. 8 is a cross-sectional view showing the manufacturing step after FIG. 7;

FIG. 9 is a cross-sectional view showing the manufacturing step after FIG. 8;

FIG. 10 is a cross-sectional view showing the manufacturing step after FIG. 9;

FIG. 11 is a cross-sectional view showing the manufacturing step after FIG. 10;

FIG. 12 is a cross-sectional view showing the manufacturing step after FIG. 11;

FIG. 13 is a cross-sectional view showing major parts of the semiconductor device according to still another embodiment of the present invention;

FIG. 14 is a cross-sectional view showing a part of manufacturing steps of a conventional semiconductor device;

FIG. 15 is a view showing the manufacturing step after FIG. 14; and

FIG. 16 is a view showing the manufacturing step after FIG. 15.

### DETAILED DESCRIPTION OF THE INVENTION

In the course of development of the present invention, the inventor studied abbut a method for effectively achieving on-current enhancement utilizing a device isolation insulating film. As a result, the inventor obtained the following findings.

As described in the Description of the Related Art, the silicone nitride film 104 is not formed on the side surface of the trench 103 near the surface of the semiconductor substrate 101 and the upper surface thereof is covered by the insulating film 106. This is because that if the silicon nitride film 104 is exposed in the trench 103 in the process of removing the silicon nitride film 102, the film 104 may excessively be etched back to be significantly away from the surface of the semiconductor substrate.

As described above, the silicon nitride film 104 must be removed at the position near the surface of the semiconductor substrate 101 in the trench 103 for manufacturing reason. It follows that the silicon nitride film 104 is not formed at the position where the largest on-current enhancement can be achieved. The silicon nitride film 104 formed only near the bottom of the trench 103 provides smaller on-current enhancement than the silicon nitride 104 formed also near the surface of the semiconductor substrate 101.

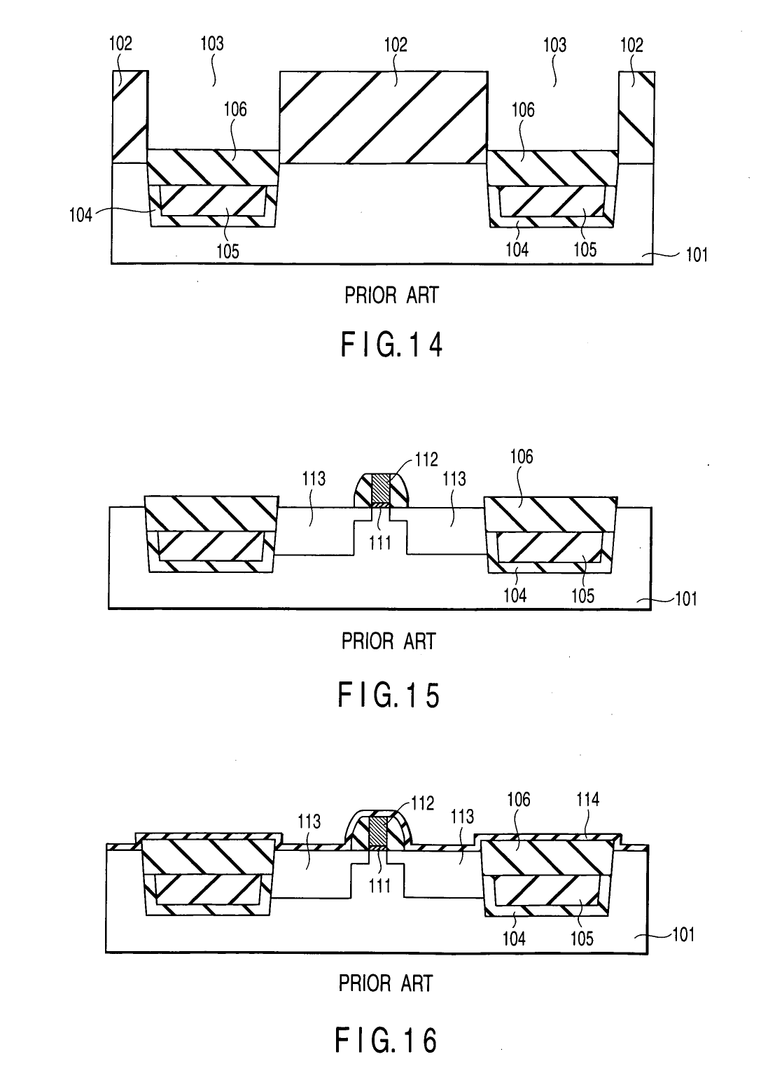

In recent years, a stress of the etching stopper film 114 is controlled to exhibit on-current enhancement comparable to that of the silicon nitride film 104. However, in the process shown in FIGS. 14 to 16, a considerable number of works are required to form the silicon nitride film 104 and etching stopper film 114. Therefore, a need arises for a manufacturing process that can effectively form a stress film for obtaining high on-current enhancement.

Hereinafter, an embodiment of the present invention accomplished based on the above findings will be described with reference to the accompanying drawings. In the following descriptions, the same reference numerals denote the same or corresponding parts, and overlapped description is omitted except when necessary.

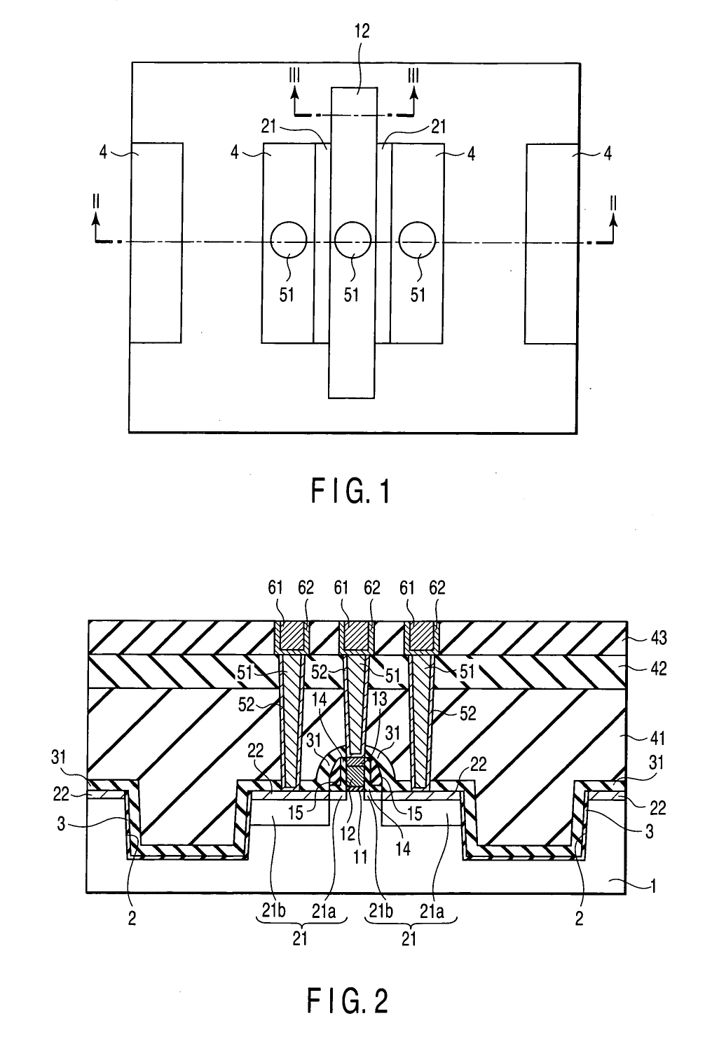

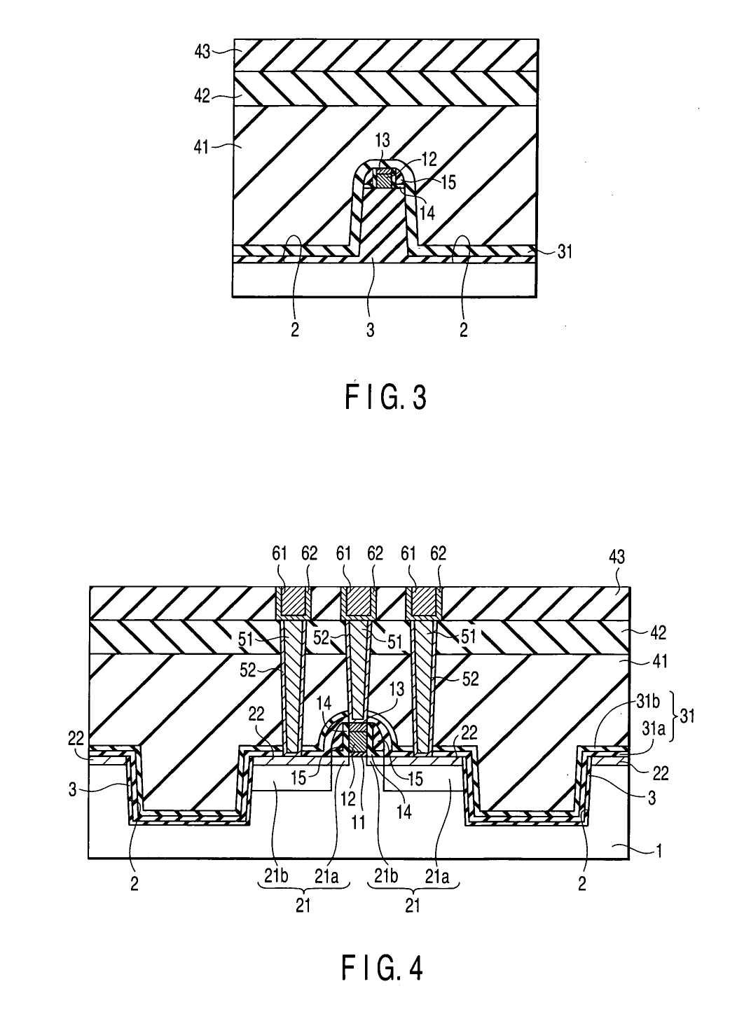

FIG. 1 is a plan view showing major parts of a semiconductor device according to an embodiment of the present invention. FIGS. 2 and 3 are cross-sectional views taken along II-II line and III-III line in FIG. 1, respectively. As shown in FIGS. 1, 2, and 3, a trench 2 constituting a device isolation region is formed in the surface of a semiconductor substrate 1 made of, e.g., silicon. The device isolation region defines a device region (active area) 4. The trench 2 is formed in the surface of the semiconductor substrate 1 at a region other than the active area 4. An insulating film 3 made of, e.g., a silicon oxide film is formed on the side surface and bottom surface of the trench 2.

A MOSFET is formed in the device region 4. The MOSFET includes at least a gate insulating film 11, a gate electrode 12, and a source/drain diffusion area 21.

The gate insulating film 11, which is formed on the surface of the semiconductor substrate 1, is made of, e.g., a silicon oxide film. The gate electrode 12, which is formed on the gate insulating film 11, is made of polysilicon doped with conductivity-enhancing impurities.

Both end portions in the vertical direction of FIG. 1 of the gate electrode 12 reach outside the device region 4. The trench 2 is not formed but the insulating film 3 is buried under the gate electrode in this device isolation region. The gate electrode 12 is positioned on the gate insulating film 11 in the device region 4 while it is positioned on the insulating film 3 in the device isolation region.

A silicide 13 is formed on the upper surface of the gate electrode 12.

An insulating film 14 made of, e.g., a silicon nitride film is formed on the side surfaces of the gate insulating film 11 and gate electrode 12. A spacer 15 made of, e.g., a silicon nitride film is formed on the side wall of the insulating film 14.

The source/drain diffusion area 21 is formed in the surface of the semiconductor substrate 1 so as to sandwich the channel region underlying the gate electrode 12 within the device region 4. The source/drain diffusion area 21 includes a lightly doped portion (Lightly Doped Drain) 21a and a heavily doped portion 21b. The lightly doped potion 21a underlies the insulating film 14 and spacer 15 and is formed in a shallow region of the semiconductor substrate 1. The heavily doped portion 21b sandwiches the lightly doped portion 21a and reaches a deeper position of the semiconductor substrate 1 than the position of the lightly doped portion 21a. A silicide 22 is formed on the surface of the source/drain diffusion area 21.

A stress film 31 is formed on the side surfaces of the spacer 15, upper surface of the gate electrode 12, surface of the semiconductor substrate 1 within the device region 4, corners formed by the trench 2 and semiconductor substrate 1, and insulating film 3 within the trench 2. The stress film 31 covers the entire surface of the insulating film 3 in the trench 21, so that it can apply a large stress to the semiconductor substrate 1. Further, the stress film 31 is formed also at a position nearest to the channel region of the MOSFET, i.e., near the surface of the semiconductor substrate 1. This enables the stress film on the side surface to apply the stress to the channel region to enhance on current. Therefore, it is possible to take advantage of on-current enhancement of the MOSFET by the stress film 31 to the fullest extent.

The stress film 31 is made of such a material and composition as to increase on-current of the MOSFET by means of a stress that the stress film 31 applies to the semiconductor substrate 1. Examples of the material of the stress film 31 include a silicon oxide film, a silicon nitride film, a silicon oxynitride film, a hafnium oxide film, an aluminum oxide film, an aluminum nitride film, a tantalum oxide film, and a titanium oxide film.

The stress film 31 has characteristics in accordance with the channel conductivity of the MOSFET that the film 31 applies the stress to. More specifically, a stress film 31 having a tensile stress is used for an n-type channel MOSFET while a stress film 31 having a compressive stress is used for a p-type channel MOSFET. When on-current of both the n-type and p-type needs to be increased using a single material, the composition of the material is appropriately controlled. In this case, different materials may be used for respective conductibility types.

The stress film 31 may have a laminated structure including a first layer 31a and second layer 31b, as shown in FIG. 4. Although the laminated structure includes two layers in the example of FIG. 4, it may include three or more layers. When the stress film 31 has the laminated structure, the abovementioned materials may be individually used for respective layers. If a layer having a tensile stress and a layer having a compressive stress are laminated, it is possible to increase on-current of both the n-type and p-type MOSFETs at the same time.

The stress film 31 functions also as an etching stopper at least on the surface of the semiconductor substrate 1 and gate electrode 12.

An interlayer insulating film 41 made of, e.g., a silicon oxide film is formed on the entire surface of the stress film 31. The interlayer insulating film 41 is buried in the trench 2 and thereby it functions also as a device isolation insulating film in the trench 2. Interlayer insulating films 42 and 43 are sequentially formed on the entire surface of the interlayer insulating film 41.

Contact plugs 51 that reach the silicides 13 and 22 are formed in the interlayer insulating films 42 and 41. The contact plug 51 is formed of a conductive material which is buried in a contact hole via a barrier metal 52.

A wiring layer 61 is formed on the interlayer insulating film 43 and its bottom contacts the contact plug 51. The wiring layer 61 is formed of a conductive material which is buried in a wiring trench via a barrier metal 62 formed on the inner surface of the wiring groove.

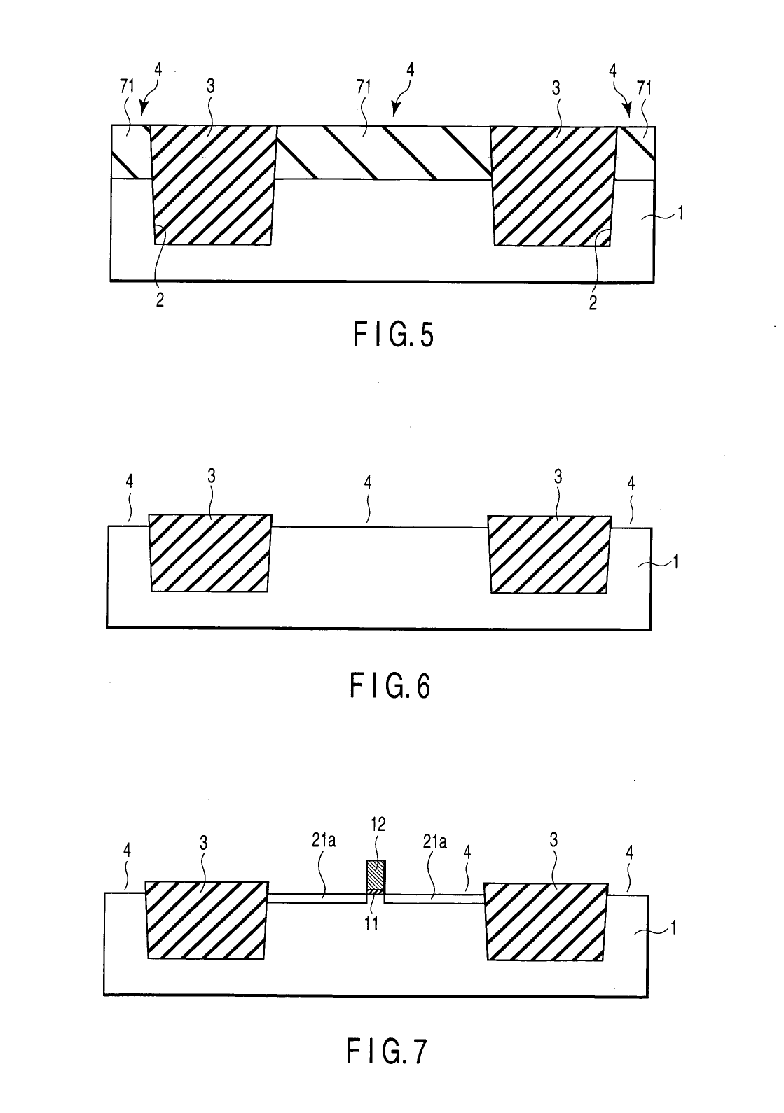

A manufacturing method of the semiconductor device shown in FIGS. 1 to 3 will next be described with reference to FIGS. 5 to 12. FIGS. 5 to 12 are cross-sectional views sequentially showing the manufacturing steps of the semiconductor device shown in FIGS. 1 to 3. FIGS. 5 to 12 show the same cross-section as that of FIG. 2. As shown in FIG. 5, an insulating film 71 having a thickness of 150 nm is formed on the semiconductor substrate 1 by, e.g., the low pressure chemical vapor deposition (LPCVD). The insulating film 71 functions as a mask used to form a trench for defining the device region and may be made of a silicon nitride film. Then, a resist film (not shown) is coated on the entire surface of the insulating film 71. Then, a pattern having an opening above the region where the trench 2 will be formed is formed on the resist film by a lithography process. The device region 4 is defined by the trench 2.

Then, The insulating film 71 is etched by an anisotropic etching such as reactive ion etching (RIE) with the resist film used as a mask. The semiconductor substrate 1 is etched by RIE or the like, by approximately 300 nm to form the trench 2.

Then, the insulating film 3 made of, e.g., a silicone oxide film is deposited on the entire surface of the structure obtained after the previous process by, e.g., the CVD. The insulating film 3 is then flattened by the chemical mechanical polishing (CMP) method using the insulating film 71 as a stopper.

Then, as shown in FIG. 6, the upper surface of the insulating film 3 is etched to a level slightly higher than the surface of the semiconductor substrate 1, more concretely, etched by approximately 100 nm from the level as shown in FIG. 5. The insulating film 71 is removed by a wet etching or the like to form the device isolation region. P-type and n-type wells (not shown) are formed by ion injection and thermal treatment.

Then, as shown in FIG. 7, the gate insulating film 11 and gate electrode 12 are formed. That is, the surface of the semiconductor substrate 1 is oxidized by, e.g., a thermal oxidation to form the gate insulating film 11. A conductive polysilicon film having a thickness of about 150 nm is formed at least on the gate insulating film and insulating film 3 by, e.g., the LPCVD.

Then, the polysilicon film is patterned into the shape of the gate electrode 12 by a lithography process and an anisotropic etching such as RIE. As shown in FIG. 1, the polysilicon film slightly enters the device isolation region from the device region. At the device isolation region, the polysilicon film is positioned on the isolating film 3.

Then, a part of the gate insulating film 11 that is not covered by the gate electrode 12 is removed by, e.g., a wet etching. Then, with the gate electrode 12 used as a mask, the lightly doped portion 21a of the source/drain diffusion area 21 is formed by ion implantation and thermal treatment of 800°C.

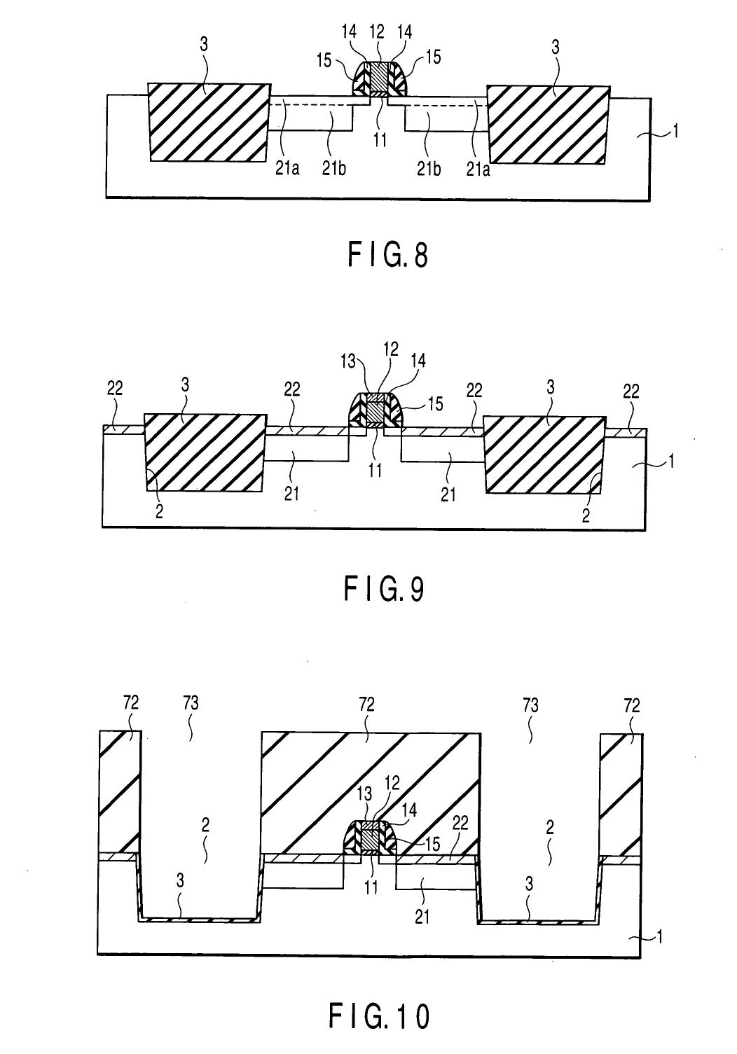

Then, as shown in FIG. 8, insulating films to become the insulating film 14 and spacer 15 are sequentially deposited on the entire surface of the structure obtained after the previous process by, e.g., the LPCVD. Then, these insulating films are etched back to form the insulating film 14 and spacer 15. Then the heavily doped portion 21b of the source/drain diffusion area 21 is formed by ion implantation and thermal treatment, with the gate electrode 12, insulating film 14, and spacer 15 used as a mask.

Then, as shown in FIG. 9, a metal film (not shown) serving as a material for the silicide is formed on the entire surface of the structure obtained after the previous process. Then, thermal treatment is performed to form suicides 13 and 22 on the gate electrode 12 and the surface of the semiconductor substrate 1 (surface of the source/drain diffusion area 21), respectively. After that, the metal film that has not formed silicide is removed.

Then, a resist film 72 is formed by coating on the entire surface obtained after the previous process. Then, a lithography process is performed to form a pattern having an opening 73 above the trench 2 (above the insulating film 3) in the resist film 72.

Then, as shown in FIG. 10, the insulating film 3 is etched back by, e.g., RIE with the resist film used as a mask. The opening 73 of the resist film 72 is made slightly smaller than the planar area of the trench 2 for possible misalignment between the pattern of the resist film and the trench 2. Therefore, the insulating film 3 remains on the side surfaces of the trench 2 after etching.

The smaller the distance between the stress film 31 and semiconductor substrate 1 facing the side surfaces of the trench 2, the larger the stress that the stress film 33 applies on the semiconductor substrate 1. Therefore, it is preferable that the insulating film 3 on the side surfaces of the trench 2 be thin in order to obtain a larger stress. However, if the insulating film 3 is completely removed, the stress film 31 is brought into contact with the surface of the trench 2, i.e., silicon, unfavorably resulting in interface states to possibly degrade characteristics of the semiconductor device. Therefore, it is preferable for the trench 2 to be covered with the thin insulating film 3.

Further, the etching back condition of the insulating film 3 includes slightly leaving the insulating film 3 on the bottom surface of the trench 2. This is because that the surface smoothness of the semiconductor substrate 1 at the bottom of the trench 2 may be impaired if the insulating film 3 is to be completely removed. That is, not only the insulating film 3 is removed but also the silicon on the bottom surface of the trench 2 is etched at some regions. If a well is formed in this portion, its characteristics are impaired to change characteristics of the semiconductor device, failing to normally function at worst.

Too thick insulating film 3 on the bottom surface of the trench 2 decreases the area of the stress film 31 on the side surfaces of the trench 2. The reduced area of the stress film 31 lowers on-current enhancement of the MOSFET. Therefore, it is preferable that the insulating film 3 on the bottom surface of the trench 2 be thin in order to obtain a larger stress. Further, it is preferable that the insulating film 3 on the bottom surface of the trench 2 be positioned deeper than at least the position of the bottom surface (junction depth) of the source/drain diffusion area 21.

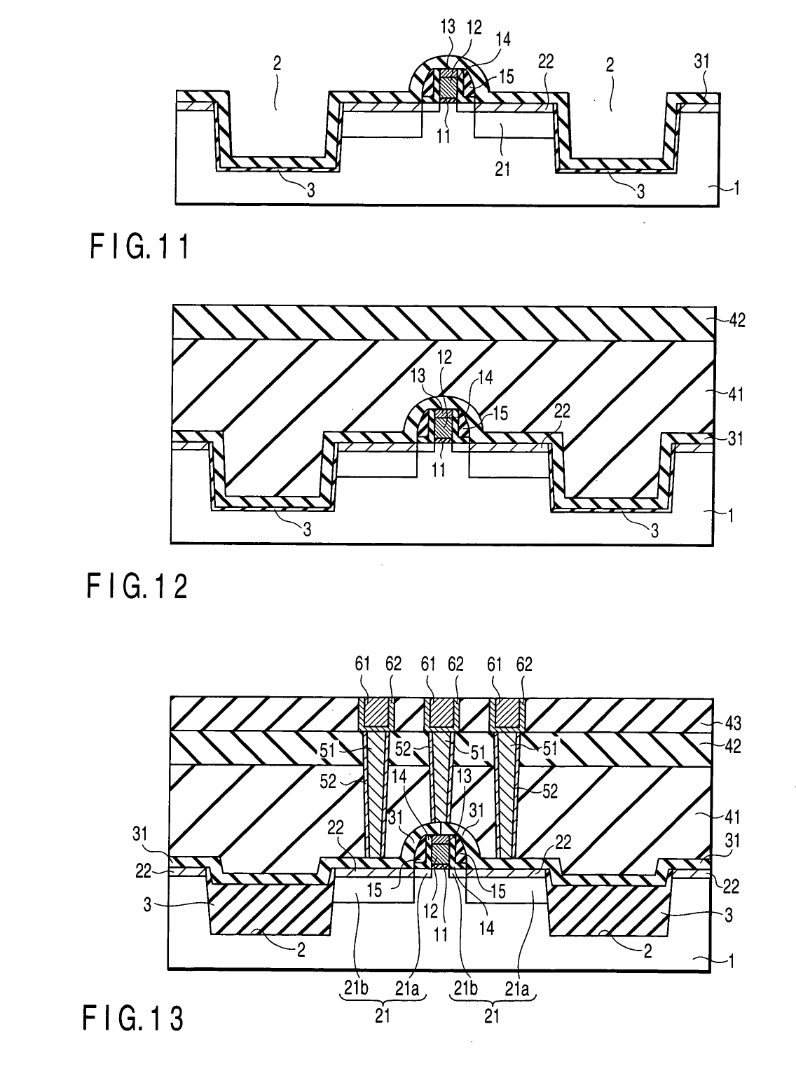

Then, as shown in FIG. 11, the stress film 31 is deposited on the entire surface of the structure obtained after the previous process by, for example, the LPCVD. The thickness of the stress film 31 is, e.g., 30 nm. As a result, the stress film 31 is formed on the gate electrode 12, spacer 15, surface of the semiconductor substrate 1, and insulating film 3. The stress film 31 has originally been formed on the gate electrode 12 and surface of the semiconductor substrate 1 as a stopper film used in following etching process for the formation of a contact hole. The formation of the film to be used for such a purpose even in the inner surface of the trench 2 enables effective formation of the stress film 31 in the trench 2 while utilizing a conventional manufacturing process of the semiconductor device.

More specifically, the stress film 104 on the surfaces of the trench 103 and etching stopper film 114 having also a function of applying a stress are formed by separate manufacturing steps in the method shown in FIGS. 14 to 16, while they can be formed by a single step in the manufacturing method according to the present embodiment. Thus, the manufacturing can be simplified.

As a result of the step shown in FIG. 11, the stress film 31 is formed on the entire surface of the trench 2, including the surface near the semiconductor substrate 1 (corners of the trench 2) at which the stress film 31 contributes most to on-current enhancement of the MOSFET.

Then, as shown in FIG. 12, the interlayer insulating film 41 having a thickness of 400 nm is deposited on the entire surface of the structure obtained after the previous process by, e.g., the LPCVD. The trench 2 is buried by the interlayer insulating film 41 at the same time. The interlayer insulating film 41 is flattened by, e.g., the CMP.

Then, the interlayer insulating film 42 having a thickness of about 200 nm is deposited on the entire surface of the interlayer insulating film 41 by, e.g., the plasma CVD.

Then, as shown in FIG. 2, contact holes that reach the silicide 13 and 22 are formed in the interlayer insulating films 41 and 42 by a lithography process and an anisotropic etching such as RIE. The barrier metal 52 having thickness of about 5 nm is formed on the inner surface of each contact hole by, for example, a sputtering. Then, the contact holes are filled with a conductive material such as tungsten by, e.g., the thermal CVD to thereby form the contact plugs 51.

Then, the interlayer insulating film 43 is formed on the entire surface obtained after the previous step. Then, the barrier metal 62 and wiring layer 61 are formed in the interlayer insulating film 43 by a lithography process, an etching, the CVD, and the like. Thereafter, another interlayer insulating film, a via plug, a wiring layer, a pad and the like are formed by known methods if necessary.

Although the insulating film 3 in the trench 2 is removed on purpose in the above description, the present invention is not limited thereto and a configuration shown in FIG. 13 may be adapted. Hereinafter, the configuration shown in FIG. 13 will be described.

A ratio between the etching rate of a film to be removed by an etching process after the trench 2 is buried by the insulating film 3 in the manufacturing step shown in FIG. 5 and that of the insulating film 3 is not sufficiently large in some cases. In such an etching process, the upper surface of the insulating film 3 may be slightly etched back. Repeated etching performed under such a condition may result in upper surface of the insulating film 3 which is lower than the surface of the semiconductor substrate 1 as shown in FIG. 13. Carrying out of the manufacturing step described using FIG. 11 on the resulted structure form the stress film 31 on the upper surface of the thick insulating film 3 in the trench 2, as shown in FIG. 13.

Also in the structure of FIG. 13, the stress film 31 is formed over the entire side surfaces of the trench 2, including the surface near the semiconductor substrate 1 at which the stress film 31 contributes most to on-current enhancement of the MOSFET. Note the insulating film 2 on the side surfaces of the trench 2 near the surface of the semiconductor substrate 1 in FIG. 13 is an oxide film naturally formed when the semiconductor device being processed is brought out from processing apparatus.

According to the semiconductor device of the embodiment of the present invention, a film formed on the gate electrode 12 and surface of the semiconductor substrate 1 as an etching stopper film extends over the inner surface of the trench 2 serving as a device isolation region. As a result, the stress film 31 is formed on the entire side surfaces of the trench 2, including the surface near the semiconductor substrate 1 at which the stress film 31 contributes most to on-current enhancement of the MOSFET. Therefore, it is possible to take advantage of on-current enhancement obtained by the stress film 31 in the trench 2 to the fullest extent.

Further, unlike the manufacturing steps shown in FIGS. 14 to 16, the stress film 31 is not yet formed when the insulating film (e.g., a silicon nitride film) 71 used in formation of the trench for defining the device region is removed. Thus, even if both the insulating film 71 and stress film 31 are removed due to similarity between their materials under a given etching condition, the coating of the silicon nitride film 104, which is inevitable in the manufacturing steps shown in FIGS. 14 to 16, is not needed for removal of the silicon nitride film 102. Therefore, the stress film 31 can be formed on the entire side surfaces of the trench 2 serving as a device isolation region.

Further, the stress film 31 extending in the trench 2 is achieved by utilizing an etching stopper film. That is, a film which is disposed on the surface of the semiconductor substrate as an etching stopper film is formed also on the inner surface of the trench 2 serving as a device isolation region in a single manufacturing process. Therefore, single process can form both a stress film which also serves as an etching stopper on the surface of the semiconductor substrate 1 and a stress film on the inner surface of the trench 2, which have been formed by separate manufacturing steps. In other words, it is possible to effectively form the stress film 31 in the region at which the stress film can contribute most on-current enhancement the most while utilizing a manufacturing process originally required.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a trench formed in a surface of the semiconductor substrate and defining a device region;
a MOSFET including a gate insulating film formed on the semiconductor substrate, a gate electrode formed on the gate insulating film, and a source/drain diffusion area sandwiching a channel region below the gate electrode;
a stress film continuously formed over the gate electrode and source/drain diffusion area and in the trench and applying a tensile stress or compressive stress to the semiconductor substrate; and
an insulating film burying the trench on the stress film.

2. The device according to claim 1, wherein
the stress film is substantially made of a material applying a tensile stress to the semiconductor substrate when the MOSFET has an n-type channel and the stress film is substantially made of a material applying compressive stress to the semiconductor substrate when the MOSFET has a p-type channel.

3. The device according to claim 1, wherein
the stress film is made of a silicon oxide film, a silicon nitride film, a silicon oxynitride film, a hafnium oxide film, an aluminum oxide film, an aluminum nitride film, a tantalum oxide film, a titanium oxide film, or a laminated film thereof.

4. The device according to claim 1, further comprising an insulating film formed on a side surface of the trench, wherein
the stress film is formed on the insulating film.

5. A method of manufacturing a semiconductor device comprising:
forming a trench which defines a device region in a surface of a semiconductor substrate;
forming a MOSFET on the surface of the semiconductor substrate, the MOSFET including a gate insulating film, a gate electrode formed on the gate insulating film, and a source/drain diffusion area sandwiching a channel region below the gate electrode;
forming a continuous stress film over the gate electrode and source/drain diffusion area and in the trench, the stress film applying a tensile stress or compressive stress to the semiconductor substrate; and
burying the trench with a first insulating film on the stress film.

6. The method according to claim 5, wherein
forming the trench includes:
forming the trench in the surface of the semiconductor substrate;
burying the trench with a second insulating film; and
lowering an upper surface of the second insulating film.

7. The method according to claim 6, wherein
lowering the upper surface of the second insulating film includes:
forming a mask material having a hole smaller than the area of an opening of the trench on the second insulating film; and
lowering the upper surface of the second insulating film below the opening of the mask material.

8. The method according to claim 6, wherein
forming the stress film includes
forming the stress film on the second insulating film on a side surface of the trench.

9. The method according to claim 5, wherein
forming the stress film includes
forming the stress film over an entire inner surface of the trench.

10. The method according to claim 5, wherein
the stress film is substantially made of a material applying a tensile stress to the semiconductor substrate when the MOSFET has an n-type channel and the stress film is substantially made of a material applying compressive stress to the semiconductor substrate when the MOSFET has a p-type channel.

11. The method according to claim 5, wherein
the stress film is made of a silicon oxide film, a silicon nitride film, a silicon oxynitride film, a hafnium oxide film, an aluminum oxide film, an aluminum nitride film, a tantalum oxide film, a titanium oxide film, or a laminated film thereof.
